(19) United States
(12) Patent Application Publication
(10) Pub. No.: US 2016/0035889 A1
(43) Pub. Date: Feb. 4, 2016

(54) STRIP-SHAPED GATE TUNNELING FIELD EFFECT TRANSISTOR USING COMPOSITE MECHANISM AND FABRICATION METHOD THEREOF

(71) Applicant: PEKING UNIVERSITY, Beijing (CN)

(72) Inventors: Ru HUANG, Beijing (CN); Qianqian HUANG, Beijing (CN); Chunlei WU, Beijing (CN); Jiaxin WANG, Beijing (CN); Zhan ZHAN, Beijing (CN); Yangyuan WANG, Beijing (CN)

(21) Appl. No.: 14/420,903

(22) PCT Filed: Jan. 8, 2014
(86) PCT No.: PCT/CN2014/070322

§ 371 Date: Feb. 10, 2015

(30) Foreign Application Priority Data
Aug. 27, 2013 (CN) 201310377553.4

(51) Int. Cl. H01L 29/78; H01L 29/417; H01L 29/66

(52) U.S. Cl. CPC H01L 29/7833; H01L 29/66492; H01L 29/41775

(57) ABSTRACT

The present invention discloses a strip-shaped gate tunneling field effect transistor using composite mechanism and a fabrication method thereof, which belongs to a field of field effect transistor logic devices and circuits in the CMOS ultra large scale integrated circuit (ULSI). According to the tunneling field effect transistor, the energy band of the channel underneath the gate is elevated by means of a change of the gate morphology and the PN junction depletion effect occurred at both sides of the strip-shaped gate, so that the sub-threshold characteristics of the transistor are improved. Meanwhile, the on-state current of the transistor is effectively increased by means of the composite mechanism introduced by the two parts of the doped source region. Moreover, the bulk leakage current, including a source-to-drain direct tunneling current and a punching through current, which comes from the two parts of the doped source region to the doped drain region can be greatly suppressed through the design of the ‘ [symbol] ’-shaped active region, so that the short channel effect is inhibited and thus the transistor can be applied with a smaller size.

### CROSS-REFERENCES TO RELATED APPLICATION

The present application claims priority of Chinese Patent Application (No. 201310377553.4), filed on Aug. 27, 2013, which is incorporated herein by reference in its entirety.

### TECHNICAL FIELD

The present invention belongs to a field of field effect transistor logic devices and circuits in the CMOS ultra large scale integrated circuit (ULSI), and particularly refers to a strip-shaped gate tunneling field effect transistor using composite mechanism and a fabrication method thereof.

### BACKGROUND OF THE INVENTION

Driven by the Moore's Law, a feature size of the conventional MOSFET continues to shrink and now enters into a nanometer scale. Consequently, negative effects such as short channel effect become more serious. Besides, effects such as drain induced barrier lowering and band-to-band tunneling cause an off-state leakage current to be continually increased. At the same time, a sub-threshold slope of the conventional MOSFET is not able to be decreased in synchronization with the shrink of the size of the MOSFET due to the limitation by the thermal potential, and thereby the power consumption increases. The concern of the power consumption now becomes the most serious problem limiting the scaling down of the MOSFET.

In order to be applied to the field of ultra-low voltage and ultra-low power consumption, a device having an ultra-steep sub-threshold slope, obtained by adopting a new turning-on mechanism and a fabrication method thereof have gained attentions in the context of small size devices. In recent years, researchers have proposed a possible solution, that is, a tunneling field effect transistor (TFET). Different from the conventional MOSFET, the TFET has source and drain regions doped with opposite types and achieves turning-on by controlling the band-to-band tunneling of the reverse-biased P-I-N junction through the gate, thereby breaking through the limitation of the sub-threshold slope 60 mV/dec of the conventional MOSFET while generating a very small leakage current. The TFET has several superior characteristics such as low leakage current, low sub-threshold slope, low operating voltage and low power consumption. However, due to the limitation of the tunneling probability and the tunneling area for the source junction, the TFET is faced with a problem of small on-state current, which is far less than that of the conventional MOSFET, and this greatly limits the application of the TFET. In addition, the TFET having a steep sub-threshold slope is difficult to be achieved in experiments. This is because it is difficult in experiments to achieve a steep doping concentration gradient at the source junction, so that the electric field at the tunneling junction is not sufficiently large when the TFET turns on, causing the sub-threshold slope of the TFET to be degraded relative to the theoretical value. Therefore, it has become an important issue of the TFET that how to achieve a steep doping concentration gradient at the source junction in order to obtain an ultra-low sub-threshold slope while obtaining a high on-state current.

### SUMMARY OF THE INVENTION

An object of the present invention is to provide a strip-shaped gate tunneling field effect transistor using composite mechanism and a fabrication method thereof. Being fully compatible with the conventional CMOS process, by changing the gate layout and the channel morphology of the conventional tunneling field effect transistor, the transistor according to the present invention equivalently achieves a steep source junction doping concentration, significantly optimizes the sub-threshold slope of the TFET, effectively suppresses the source-to-drain direct tunneling current in the context of short channel and maintains a low leakage current. Moreover, a doping with an opposite type to a deep junction depth at the source region, on one hand, can further optimize the tunneling junction of the source region so as to further increase the electric field generated when the band-to-band tunneling occurs, thereby optimizing the sub-threshold characteristics of the TFET, and on the other hand, can cause a large forward PN junction current under a slightly higher gate voltage, thereby optimizing the turn-on current. Meanwhile, a lightly doped drain region can effectively inhibit the ambipolar effect of the TFET.

The technical solutions of the present invention are as follows.

A tunneling field effect transistor according to the present invention includes a semiconductor substrate, a doped source region, a doped drain region, a control gate and a gate dielectric layer, and the doped source and drain regions are located at both sides of the control gate, respectively, wherein the doped source region consists of two parts, namely a highly doped region of shallow junction and a lightly doped region of deep junction, which are doped with impurities having different doping types; the highly doped source region of shallow junction has a doping concentration of 1×10²⁰ cm⁻³ to 1×10²¹ cm⁻³ and a junction depth less than 20 nm, and the doped drain region and the lightly doped source region of deep junction both have a doping concentration of 1×10¹⁸ cm⁻³ to 1×10¹⁹ cm⁻³ and a junction depth, typically more than 40 nm, greater than a sum of the junction depth of the source region of shallow junction and a width of a depletion layer, wherein the lightly doped source region of deep junction and the doped drain region have the same doping type and concentration, and are formed simultaneously in a self-aligning manner by means of the strip-shaped gate. Comparing with the control gate of the conventional tunneling field effect transistor, the control gate according to the present invention has a strip-shaped structure in which a length is greater than a width, and a side of the control gate is connected to the doped drain region and the other side of the control gate extends laterally towards the doped source region, that is, a portion of the strip-shaped control gate is located between the doped source and drain regions, and the other portion thereof extends into the doped source region; both of the two parts of the doped source region are formed in a self-aligning manner by means of the strip-shaped gate; underneath the strip-shaped gate exists no doped area but a channel region, in which the active region between the doped source and drain regions is only located, so that the active region of the transistor exhibits a ‘ [symbol] ’-shape from a top view. The substrate has a doping concentration of 1×10¹⁴ cm⁻³ to 1×10¹⁷ cm⁻³. The lightly doped source region has a doped area larger than the highly doped source region so that the two parts of the doped source region can be electrically led out simultaneously. A ratio of a length of the control gate lying between the doped source and drain regions to a length of the control gate extending into the doped source region is 1:1-1:5; a width of the control gate is twice less than a width of the depletion layer in the source region, which is in a range of 25 nm-1.5 μm.

A fabrication method of the tunneling field effect transistor described above comprises the following steps:

(1) forming a ‘ [symbol] ’-shaped active region on a semiconductor substrate by photolithography and etching;

(2) growing a gate dielectric layer;

(3) depositing material for a control gate, and forming a pattern of a strip-shaped control gate by performing photolithography and etching;

(4) forming lightly doped source and drain regions by performing ion implantation in a self-aligning manner using the control gate as a mask;

(5) exposing a highly doped source region by photolithography and forming the highly doped source region of shallow junction, which has another doping type, by performing ion implantation using a photoresist and the control gate as the mask, and then performing rapid high temperature thermal annealing to activate impurities in the source and drain regions;

(6) performing subsequent CMOS processes comprising depositing a passivation layer, opening a contact hole, and metalizing so that the tunneling field effect transistor as shown in FIG. 5 is fabricated.

In the fabrication method described above, material of the semiconductor substrate in the step (1) is selected from Si, Ge, SiGe, GaAs or other binary or ternary compound semiconductors based on Group II-VI, III-V and IV-IV, or silicon on insulator (SOI) or germanium on insulator (GOD.

In the fabrication method described above, material of the gate dielectric layer in the step (2) is selected from SiO₂, Si₃N₄, and high-K gate dielectric material.

In the fabrication method described above, the growing of the gate dielectric layer in the step (2) is selected from one of the following methods: conventional thermal oxidation, nitrogen-doped thermal oxidation, chemical vapor deposition and physical vapor deposition.

In the fabrication method described above, the material for the control gate in the step (3) is selected from doped polysilicon, metal cobalt, nickel and other metal, or metal silicide.

The present invention has the following technical effects.

Firstly, by means of the strip-shaped gate extending into the source region, a larger tunneling area under the same area of active region can be achieved, and thus a higher turn-on current compared with the conventional TFET may be obtained. Since low-concentration impurities are implanted into a deeper junction depth compared with the high-concentration impurities, the impurities at the deeper junction depth are not compensated and depleted, thereby providing a large forward PN junction turn-on current under a high gate voltage and greatly improving the on-state current of the device. Furthermore, since the low-concentration impurities of an opposite type are implanted into the source region in a deep junction manner, a steeper band bending may be obtained at the tunnel junction of the source region, allowing a larger electric field to be generated when the band-to-band tunneling occurs and further improving the sub-threshold slope of the TFET.

Secondly, being fully compatible with the conventional CMOS process, the energy band of the channel underneath the gate is elevated by means of a change of the gate morphology and by means of the PN junction depletion effect occurred at both sides of the strip-shaped gate, and therefore a steeper energy band and a narrower tunneling barrier width compared with the conventional TFET may be obtained when the band-to-band tunneling occurs, equivalently achieving a steep doping concentration gradient at the tunneling junction, and thereby significantly improving the sub-threshold characteristics of the conventional TFET. Moreover, a bulk leakage current, including a source-to-drain direct tunneling current and a punching through current, which comes from the two parts of the doped source region to the doped drain region, can be greatly suppressed through the design of the ‘ [symbol] ’-shaped active region, and the short channel effect can be inhibited so that the device can be applied with a smaller size. Meanwhile, the design of the lightly doped drain region can effectively suppress the tunneling current coming from the drain junction, inhibits the ambipolar effect of the TFET, and further reduce the leakage current of the TFET.

In short, the device structure according to the present invention adopts designs of the strip-shaped gate structure, the ‘ [symbol] ’-shaped active region and the two parts of the doped source region, and introduces the composite mechanism of the band-to-band tunneling and the forward PN junction. The device structure, on one hand, effectively modulates the tunneling junction in the source region of the conventional TFET, achieves a effect that the source junction has a steeper energy band bending and a larger tunneling electric field, and improves the sub-threshold characteristics of the TFET; on the other hand, the introduced larger tunneling area and the forward PN junction current can greatly increase the on-state current of the TFET, while suppressing the leakage current in case of short channel. Comparing with the conventional TFET, the fabrication process is simple, and a higher turn-on current and a steeper sub-threshold slope can be obtained and a low leakage current can be maintained. Therefore, the device can be adopted in the field of low power consumption, thereby possessing a high practical value.

### BRIEF DESCRIPTION OF THE DRAWINGS

FIG. 1 is schematic view illustrating a process step for forming a ‘ [symbol] ’-shaped active region on a semiconductor substrate by photolithography, where (a) corresponds to a perspective view of the device; (b) corresponds to a top view of the device.

FIG. 2 is a schematic view of the device in which a gate dielectric layer is grown on the active region formed by etching and a strip-shaped control gate is formed by photolithography and etching, where (a) corresponds to a perspective view of the device; (b) corresponds to a top view of the device.

FIG. 3 is a schematic view of the device in which lightly doped source and drain regions are formed by ion implantation, where (a) corresponds to a perspective view of the device; (b) corresponds to a top view of the device.

FIG. 4 is a schematic view of the device in which a highly doped source region is exposed by photolithography and the highly doped source region of shallow junction, which has a different doping type, is formed by ion implantation, where (a) corresponds to a perspective view of the device; (b) corresponds to a top view of the device.

FIG. 5 is a device schematic view of a strip-shaped gate tunneling field effect transistor using composite mechanism according to the present invention, where (a) corresponds to a perspective view of the device; (b) corresponds to a cross-sectional view of the device taken along a direction of a dotted line AA′ of FIG. 5(a); (c) corresponds to a cross-sectional view of the device taken along a direction of a dotted line BB′ of FIG. 5(a).

In the drawings:

| | |
|---|---|
| 1 - a semiconductor substrate | 2 - a photoresist |
| 3 - a gate dielectric layer | 4 - a control gate |
| 5 - a lightly doped drain region | |

6 - a lightly doped source region of deep junction
7 - a highly doped source region of shallow junction, having an opposite
doping

type

### DETAILED DESCRIPTION OF THE EMBODIMENTS

Hereinafter, the present invention will be further described by the examples. It is noted that, the disclosed embodiments are intended to help further understand the present invention, but it will be appreciated to those skilled in the art that various substitutes and modifications may be made possible without departing from the spirit and scope defined by the present invention and the following claims. Accordingly, the present invention should not be limited to the contents disclosed by the embodiments, and the protection scope of the present invention should be defined by the claims.

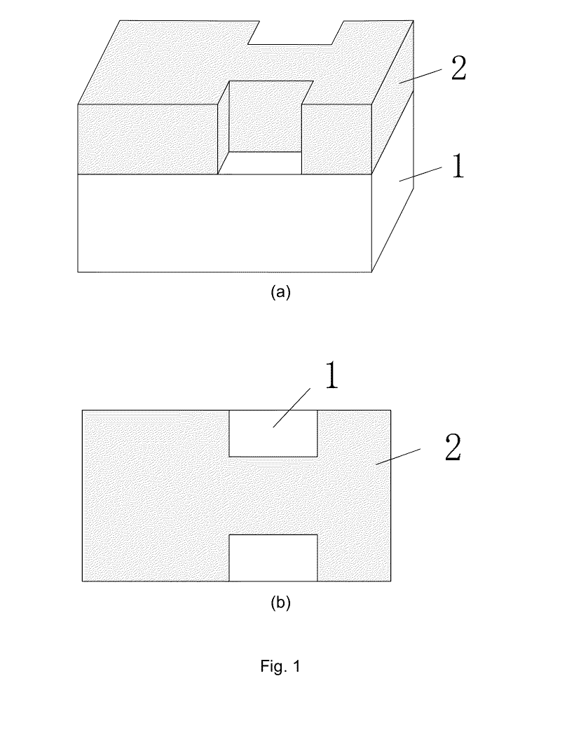

A specific example of a fabrication method according to the present invention includes the process steps shown in FIG. 1 to FIG. 5.

1. A bulk silicon substrate 1 having a crystal orientation of (100) is selected. The substrate is lightly doped. A pattern of a ‘ [symbol] ’-shaped active region as shown in FIG. 1(a) and FIG. 1(b) is formed on the substrate by photolithography. Subsequently, the ‘ [symbol] ’-shaped active region is formed through deeply etching the silicon substrate by using a thick layer of photoresist 2 as a mask.

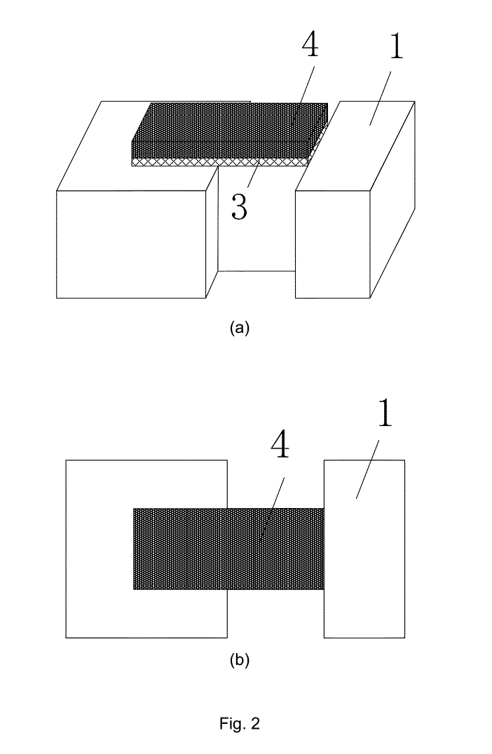

2. A gate dielectric layer 3 is thermally grown. The gate dielectric layer is SiO₂ and has a thickness of 1˜5 nm. A gate material layer 4 is deposited. The gate material layer is a doped polysilicon layer and has a thickness of 150˜300 nm. A pattern of a strip-shaped gate is formed by photolithography. The gate material layer 4 is etched to the gate dielectric layer 3, as shown in FIG. 2 (a) and FIG. 2(b). A width of the strip-shaped gate is typically 1 μm.

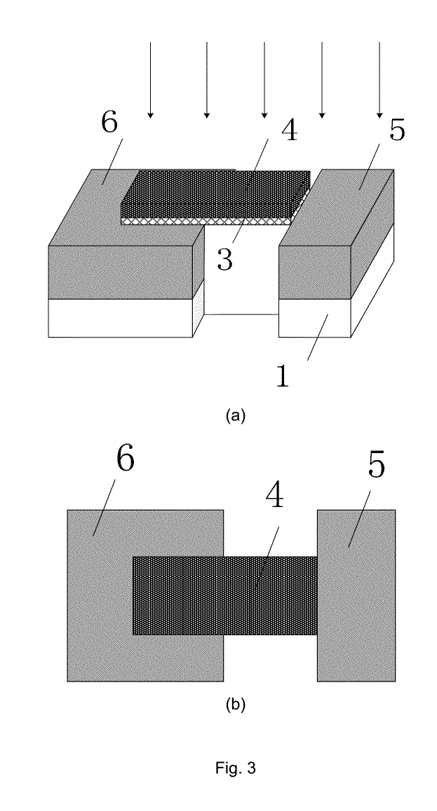

3. As shown in FIG. 3(a) and FIG. 3(b), a doped drain region 5 and a lightly doped source region 6 of deep junction are formed by performing P ion implantation in a self-aligning manner using the strip-shaped gate as a mask. The energy for ion implantation is 70 keV and the implanted impurities are BF₂⁺.

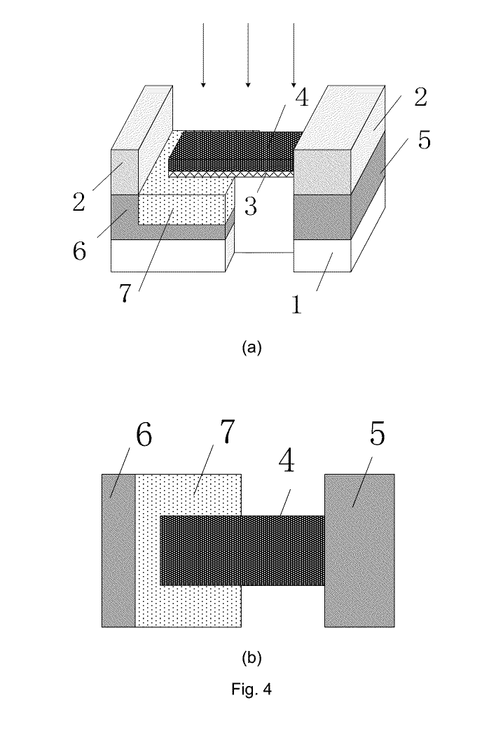

5. As shown in FIG. 4(a) and FIG. 4(b), a pattern of a highly doped source region is formed by photolithography. A highly doped source region 7 of shallow junction is formed by performing N⁺ ion implantation using a photoresist 2 and the gate as a mask. The energy for ion implantation is 40 keV and the implanted impurities are As⁺. A rapid thermal annealing is performed to activate the impurities doped in the source and drain regions.

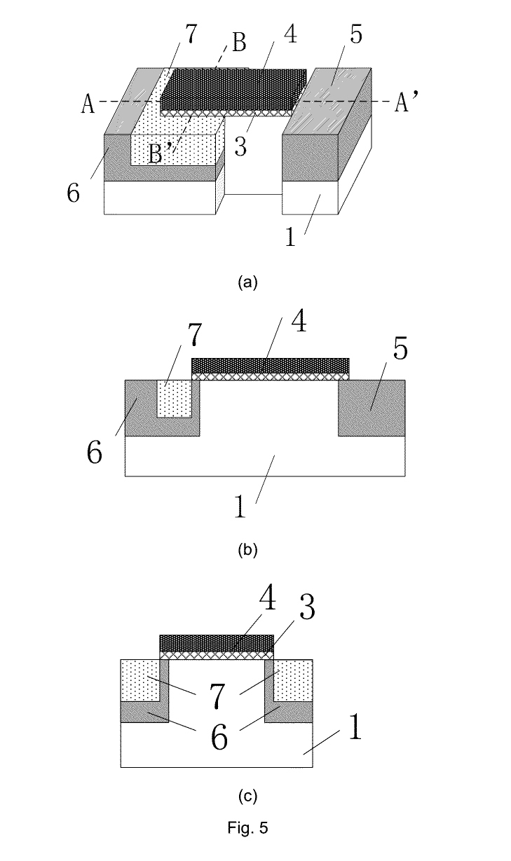

6. Finally, subsequent CMOS processes, including depositing a passivation layer, opening a contact hole and metalizing and so on are performed conventionally. As a result, the strip-shaped gate tunneling field effect transistor using composite mechanism is fabricated, as shown in FIG. 5.

Although the present invention is disclosed above by the preferred embodiment, however, it is not intended to limit the present invention. Without departing from the scope of the technical solution of the present invention, a number of variations and modifications may be made possible to the technical solution of the present invention using the method and technical contents disclosed above, or equivalent embodiments may be modified. Therefore, any simple modifications, equivalent changes and modifications made to the above embodiments according to the technical spirit of the present invention without departing from the contents of the technical solution of the present invention all fall into the protection scope of the technical solution of present invention.

1. A tunneling field effect transistor comprising a semiconductor substrate, a doped source region, a doped drain region, a control gate and a gate dielectric layer, and the doped source and drain regions are located at both sides of the control gate, respectively, wherein,
the doped source region comprising two parts, namely a first doped region of shallow junction and a second doped region of deep junction, which are doped with impurities having different doping types;
the first doped region has a doping concentration of 1×10²⁰ cm⁻³ to 1×10²¹ cm⁻³ and a junction depth less than 20 nm, and the second doped region has a doping concentration of 1×10¹⁸ cm⁻³ to 1×10¹⁹ cm⁻³ and a junction depth greater than a sum of the junction depth of the first doped region and a width of a depletion layer;
the second doped region has a larger doping area than the first doped region;
the control gate has a strip-shaped structure in which a length is greater than a width, a side of the control gate being connected to the doped drain region and an other side of the control gate extending laterally towards the doped source region; and
underneath the strip-shaped structure exists a channel region, in which an active region between the doped source and drain regions is located, so that the active region of the transistor exhibits a ‘ [symbol] ’-shape from a top view.

2. The tunneling field effect transistor according to claim 1, wherein the second doped region and the doped drain region have the same doping type and concentration and are formed simultaneously in a self-aligning manner by means of the strip-shaped structure.

3. The tunneling field effect transistor according to claim 1, wherein the semiconductor substrate has a doping concentration of 1×10¹⁴ cm⁻³ to 1×10¹⁷ cm⁻³.

4. The tunneling field effect transistor according to claim 1, wherein a ratio of a length of the control gate lying between the doped source and drain regions to a length of the control gate extending into the doped source region is 1:1-1:5; and a width of the control gate is twice less than a width of the depletion layer in the source region, which is in a range of 25 nm-1.5 μm.

5. A fabrication method for a tunneling field effect transistor, the method comprising:
forming a ‘ [symbol] ’-shaped active region on a semiconductor substrate by photolithography and etching;
growing a gate dielectric layer;
depositing material for a control gate, and forming a pattern of a strip-shaped control gate by performing photolithography and etching;
forming a first doped source and drain regions by performing ion implantation in a self-aligning manner using the control gate as a mask, the first doped source and drain regions having a doping concentration of 1×10¹⁸ cm⁻³ to 1×10¹⁹ cm⁻³;
exposing a second doped source region by photolithography, the second doped source region having a doping concentration of 1×10²¹¹ cm⁻³ to 1×10²¹ cm⁻³, and forming the second doped source region of shallow junction, which has another doping type, by performing ion implantation using a photoresist and the control gate as the mask, and then performing annealing to activate impurities in the source and drain regions; and
performing subsequent CMOS processes comprising depositing a passivation layer, opening a contact hole, and metalizing.

6. The fabrication method according to claim 5, wherein material of the semiconductor substrate is selected from Si, Ge, SiGe, GaAs or other binary or ternary compound semiconductors based on Groups III-V and IV-IV, or silicon on insulator or germanium on insulator.

7. The fabrication method according to claim 5, wherein material of the gate dielectric layer is selected from SiO₂, Si₃N₄, and high-K gate dielectric material.

8. The fabrication method according to claim 5, wherein the growing of the gate dielectric layer is selected from one of the following methods: conventional thermal oxidation, nitrogen-doped thermal oxidation, chemical vapor deposition and physical vapor deposition.

9. The fabrication method according to claim 5, wherein the material for the control gate is selected from doped polysilicon, metal cobalt, nickel and other metal, or metal silicide.
